(19) United States
(12) Patent Application Publication
(10) Pub. No.: US 2026/0068177 A1
(43) Pub. Date: Mar. 5, 2026

(54) MEMORY DEVICES AND METHODS FOR FORMING THE SAME

(71) Applicant: YANGTZE MEMORY TECHNOLOGIES CO., LTD., Wuhan (CN)

(72) Inventors: Danyang Li, Wuhan (CN); Yu Wang, Wuhan (CN); Xikai Sun, Wuhan (CN)

(21) Appl. No.: 18/897,808

(22) Filed: Sep. 26, 2024

Related U.S. Application Data
(63) Continuation of application No. PCT/CN2024/115430, filed on Aug. 29, 2024.

(51) Int. Cl. H10B 80/00; G11C 11/408; G11C 11/4094; H01L 23/00; H01L 25/00; H01L 25/065; H01L 25/18; H10B 12/00

(52) U.S. Cl. CPC H10B 80/00; G11C 11/4085; G11C 11/4094; H10B 12/315; H10B 12/50

(57) ABSTRACT

In certain aspects, a memory device includes a memory array structure including memory blocks, and a peripheral circuit structure stacked with the memory array structure in a vertical direction and including word line drivers and precharge/discharge voltage drivers. The word line drivers are arranged in a first lateral direction and at least partially overlap with the memory blocks in the memory array structure in the vertical direction. Each of the precharge/discharge voltage drivers includes a first circuit and a second circuit physically separated by a respective one of the word line drivers in a second lateral direction perpendicular to the first lateral direction.

### CROSS-REFERENCE TO RELATED APPLICATIONS

This application is a continuation of International Application No. PCT/CN2024/115430, filed on Aug. 29, 2024, which is hereby incorporated by reference in its entirety.

### BACKGROUND

The present disclosure relates to memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In one aspect, a memory device includes a memory array structure including memory blocks, and a peripheral circuit structure stacked with the memory array structure in a vertical direction and including word line drivers and precharge/discharge voltage drivers. The word line drivers are arranged in a first lateral direction and at least partially overlap with the memory blocks in the memory array structure in the vertical direction. Each of the precharge/discharge voltage drivers includes a first circuit and a second circuit physically separated by a respective one of the word line drivers in a second lateral direction perpendicular to the first lateral direction.

In some implementations, the second circuits of the precharge/discharge voltage drivers in the peripheral circuit structure overlap with the memory blocks in the memory array structure in the vertical direction.

In some implementations, the first circuit of the precharge/discharge voltage driver includes a precharge/discharge circuit, and the second circuit of the precharge/discharge voltage driver includes an evaluating circuit.

In some implementations, the first circuit is coupled to the second circuit by one control signal routing across the respective word line driver.

In some implementations, the word line drivers are arranged in a straight-line along edges of the memory blocks, and the first circuits of the precharge/discharge voltage drivers in the peripheral circuit structure are offset from the memory blocks in the memory array structure.

In some implementations, the word line drivers are arranged in a zig-zag manner along edges of the memory blocks, and the first circuits of the precharge/discharge voltage drivers in the peripheral circuit structure overlap with the memory blocks in the memory array structure in the vertical direction and are arranged in regions between the edges of the memory blocks and the word line drivers.

In some implementations, each of the precharge/discharge voltage drivers is coupled to a respective one of the memory blocks and configured to precharge or discharge word lines of the respective memory blocks.

In some implementations, the first lateral direction is a bit line direction, and the second lateral direction is a word line direction.

In some implementations, the memory array structure includes first bonding contacts, and the peripheral circuit structure includes second bonding contacts in contact with the first bonding contacts in the vertical direction.

In some implementations, each of the memory blocks includes dynamic random-access memory (DRAM) cells.

In another aspect, a method for forming a memory device is disclosed. A memory array structure including memory blocks is formed. A peripheral circuit structure including word line drivers and precharge/discharge voltage drivers is formed. The word line drivers are formed in a first lateral direction. Each of the precharge/discharge voltage drivers includes a first circuit and a second circuit physically separated by a respective one of the word line drivers in a second lateral direction perpendicular to the first lateral direction. The word line drivers in the peripheral circuit structure at least partially overlap with the memory blocks in the memory array structure in a vertical direction.

In some implementations, the memory array structure and the peripheral circuit structure are bonded.

In some implementations, the second circuits of the precharge/discharge voltage drivers in the peripheral circuit structure overlap with the memory blocks in the memory array structure in the vertical direction.

In some implementations, the first circuit of the precharge/discharge voltage driver includes a precharge/discharge circuit, and the second circuit of the precharge/discharge voltage driver includes an evaluating circuit.

In some implementations, the first circuit is coupled to the second circuit by one control signal routing across the respective word line driver.

In some implementations, the word line drivers are formed in a straight-line along edges of the memory blocks, and the first circuits of the precharge/discharge voltage drivers in the peripheral circuit structure are offset from the memory blocks in the memory array structure.

In some implementations, the word line drivers are formed in a zig-zag manner along edges of the memory blocks, and the first circuits of the precharge/discharge voltage drivers in the peripheral circuit structure overlap with the memory blocks in the memory array structure in the vertical direction and are formed in regions between the edges of the memory blocks and the word line drivers.

In some implementations, each of the precharge/discharge voltage drivers is coupled to a respective one of the memory blocks and configured to precharge or discharge word lines of the respective memory blocks.

In some implementations, the first lateral direction is a bit line direction, and the second lateral direction is a word line direction.

In some implementations, the memory array structure includes first bonding contacts, and the peripheral circuit structure includes second bonding contacts in contact with the first bonding contacts in the vertical direction after the bonding.

In some implementations, the bonding includes hybrid bonding in a face-to-face manner.

In some implementations, each of the memory blocks includes DRAM cells.

In still another aspect, a system includes a memory device and a memory controller coupled to the memory device and configured to control the memory device. The memory device includes a memory array structure including memory blocks, and a peripheral circuit structure stacked with the memory array structure in a vertical direction and including word line drivers and precharge/discharge voltage drivers. The word line drivers are arranged in a first lateral direction and at least partially overlap with the memory blocks in the memory array structure in the vertical direction. Each of the precharge/discharge voltage drivers includes a first circuit and a second circuit physically separated by a respective one of the word line drivers in a second lateral direction perpendicular to the first lateral direction.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates a schematic view of a cross-section of a 3D memory device, according to some aspects of the present disclosure.

FIG. 1B illustrates a schematic view of a cross-section of another 3D memory device, according to some aspects of the present disclosure.

FIG. 2 illustrates a schematic diagram of a memory device including peripheral circuits and an array of memory cells each having a vertical transistor, according to some aspects of the present disclosure.

FIG. 3 illustrates a schematic circuit diagram of a memory device including peripheral circuits and an array of dynamic random-access memory (DRAM) cells, according to some aspects of the present disclosure.

FIG. 4 illustrates a schematic circuit diagram of a memory device including peripheral circuits and an array of phase-change memory (PCM) cells, according to some aspects of the present disclosure.

FIG. 5 illustrates a side view of a cross-section of a 3D memory device including vertical transistors, according to some aspects of the present disclosure.

FIG. 6 illustrates a schematic plan view of a memory device, according to some aspects of the present disclosure.

FIGS. 7A and 7B illustrate schematic plan views of a memory block and peripheral circuits overlapping with the memory block in a memory device, according to various aspects of the present disclosure.

FIG. 8 illustrates a schematic plan view of a memory device including memory blocks and precharge/discharge voltage drivers.

FIGS. 9A and 9B illustrate schematic plan views of a memory device including memory blocks and precharge/discharge voltage drivers, according to various aspects of the present disclosure.

FIGS. 10A and 10B illustrate circuit diagrams of a precharge voltage driver and a discharge voltage driver, respectively, according to some aspects of the present disclosure.

FIG. 11 illustrates a flowchart of a method for forming a 3D memory device, according to some aspects of the present disclosure.

FIG. 12 illustrates a block diagram of an exemplary system having a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

By vertically stacking a memory array device chip above a peripheral device chip or vice versa, the cell density of the resulting 3D memory device can be increased. Moreover, by decoupling the peripheral device processing and the memory array device processing, the thermal budget associated with processing the memory array device is not limited by the performance requirement of the peripheral device. Similarly, the peripheral device performance is not impacted by the memory array device processing. For example, the peripheral device and the memory array device can be separately fabricated on different substrates so that certain high-temperature processes for fabricating the memory array device will not adversely affect the fabrication of the peripheral device (e.g., avoid excess diffusion of the dopants, control the doping concentration and/or thickness of ion implantation, etc.).

When vertically stacking a memory array device chip and a peripheral device chip, interconnect routing is an important requirement because it directly affects the amount of area required and the electrical performance associated with the coupling between different interconnects. For example, too many routings across areas with high voltage devices (e.g., word line drivers) may be difficult due to the limited spaces and may increase signal noise because of the coupling effect.

To address one or more of the aforementioned issues, the present disclosure introduces a solution in which different portions of certain peripheral circuits (e.g., precharge voltage drivers and discharge voltage drivers) are detached and physically separated into different regions to optimize the interconnect routing. As a result, the number of routings across areas with high voltage devices (e.g., word line drivers) can be reduced, which in turn can increase the margin of chip layout design and reduce the chip size and coupling effect. According to some aspects of the present disclosure, the precharge/discharge circuit and the evaluating circuit of each precharge/discharge voltage driver can be placed on different sides of a respective word line driver in the word line direction and coupled by one control signal routing across the respective word line driver.

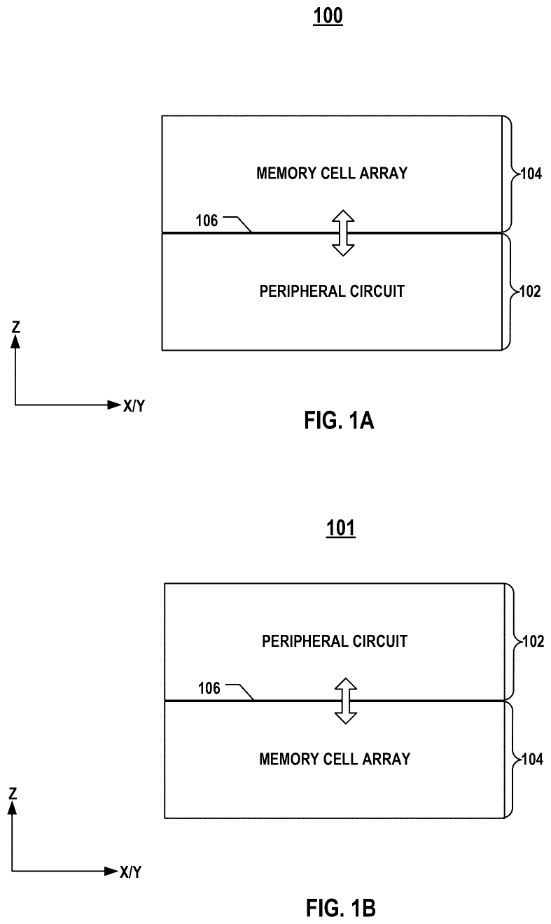

FIG. 1A illustrates a schematic view of a cross-section of a 3D memory device 100, according to some aspects of the present disclosure. 3D memory device 100 represents an example of a bonded chip. The components of 3D memory device 100 (e.g., memory cell array and peripheral circuits) can be formed separately on different substrates and then joined to form a bonded chip. 3D memory device 100 can include a first semiconductor structure 102 (also referred to herein as “peripheral circuit structure”) including the peripheral circuits of a memory cell array. 3D memory device 100 can also include a second semiconductor structure 104 (also referred to herein as “memory array structure”) including the memory cell array. The peripheral circuits (a.k.a. control and sensing circuits) can include any suitable digital, analog, and/or mixed-signal circuits used for facilitating the operations of the memory cell array. For example, the peripheral circuit can include one or more of a page buffer, a decoder (e.g., a row decoder and a column decoder), a sense amplifier, a driver (e.g., a word line driver, a precharge voltage driver, and a discharge voltage driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in first semiconductor structure 102 use complementary metal-oxide-semiconductor (CMOS) technology, e.g., which can be implemented with logic processes, according to some implementations.

As shown in FIG. 1A, 3D memory device 100 can also include second semiconductor structure 104 including an array of memory cells (memory cell array) that can use transistors as the switch and selecting devices. In some implementations, the memory cell array includes an array of DRAM cells. For ease of description, a DRAM cell array may be used as an example for describing the memory cell array in the present disclosure. But it is understood that the memory cell array is not limited to DRAM cell array and may include any other suitable types of memory cell arrays that can use transistors as the switch and selecting devices, such as phase-change memory (PCM) cell array, static random-access memory (SRAM) cell array, ferroelectric random-access memory (FRAM) cell array, resistive memory cell array, magnetic memory cell array, spin transfer torque (STT) memory cell array, to name a few, or any combination thereof.

Second semiconductor structure 104 can be a DRAM device in which memory cells are provided in the form of an array of DRAM cells. In some embodiments, each DRAM cell includes a capacitor for storing a bit of data as a positive or negative electrical charge as well as one or more transistors (a.k.a. pass transistors) that control (e.g., switch and selecting) access to it. In some implementations, each DRAM cell is a one-transistor, one-capacitor (1T1C) cell. Since transistors always leak a small amount of charge, the capacitors will slowly discharge, causing information stored in them to drain. As such, a DRAM cell has to be refreshed to retain data, for example, by the peripheral circuit in first semiconductor structure 102, according to some implementations.

As shown in FIG. 1A, 3D memory device 100 further includes a bonding interface 106 vertically between (in the vertical direction, e.g., the z-direction in FIG. 1A) first semiconductor structure 102 and second semiconductor structure 104. First and second semiconductor structures 102 and 104 can be fabricated separately (and in parallel in some implementations) such that the thermal budget of fabricating one of first and second semiconductor structures 102 and 104 does not limit the processes of fabricating another one of first and second semiconductor structures 102 and 104. Moreover, a large number of interconnects (e.g., bonding contacts) can be formed through bonding interface 106 to make direct, short-distance (e.g., micron-level) electrical connections between first semiconductor structure 102 and second semiconductor structure 104, as opposed to the long-distance (e.g., millimeter or centimeter-level) chip-to-chip data bus on the circuit board, such as printed circuit board (PCB), thereby eliminating chip interface delay and achieving high-speed input/output (I/O) throughput with reduced power consumption. Data transfer between the memory cell array in second semiconductor structure 104 and the peripheral circuits in first semiconductor structure 102 can be performed through the interconnects (e.g., bonding contacts) across bonding interface 106. By vertically integrating first and second semiconductor structures 102 and 104, the chip size can be reduced, and the memory cell density can be increased.

It is understood that the relative positions of stacked first and second semiconductor structures 102 and 104 are not limited. FIG. 1B illustrates a schematic view of a cross-section of another exemplary 3D memory device 101, according to some implementations. Different from 3D memory device 100 in FIG. 1A in which second semiconductor structure 104 including the memory cell array is above first semiconductor structure 102 including the peripheral circuits, in 3D memory device 101 in FIG. 1B, first semiconductor structure 102 including the peripheral circuit is above second semiconductor structure 104 including the memory cell array. Nevertheless, bonding interface 106 is formed vertically between first and second semiconductor structures 102 and 104 in 3D memory device 101, and first and second semiconductor structures 102 and 104 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously. Data transfer between the memory cell array in second semiconductor structure 104 and the peripheral circuits in first semiconductor structure 102 can be performed through the interconnects (e.g., bonding contacts) across bonding interface 106.

It is noted that x, y, and z axes are included in FIGS. 1A and 1B to further illustrate the spatial relationship of the components in 3D memory devices 100 and 101. The substrate of the 3D memory device includes two lateral surfaces extending laterally in the x-y plane: a top surface on the front side of the wafer on which the semiconductor devices can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of the 3D memory device is determined relative to the substrate of the 3D memory device in the z-direction (the vertical direction perpendicular to the x-y plane, e.g., the thickness direction of the substrate) when the substrate is positioned in the lowest plane of the 3D memory device in the z-direction. The same notion for describing the spatial relationships is applied throughout the present disclosure.

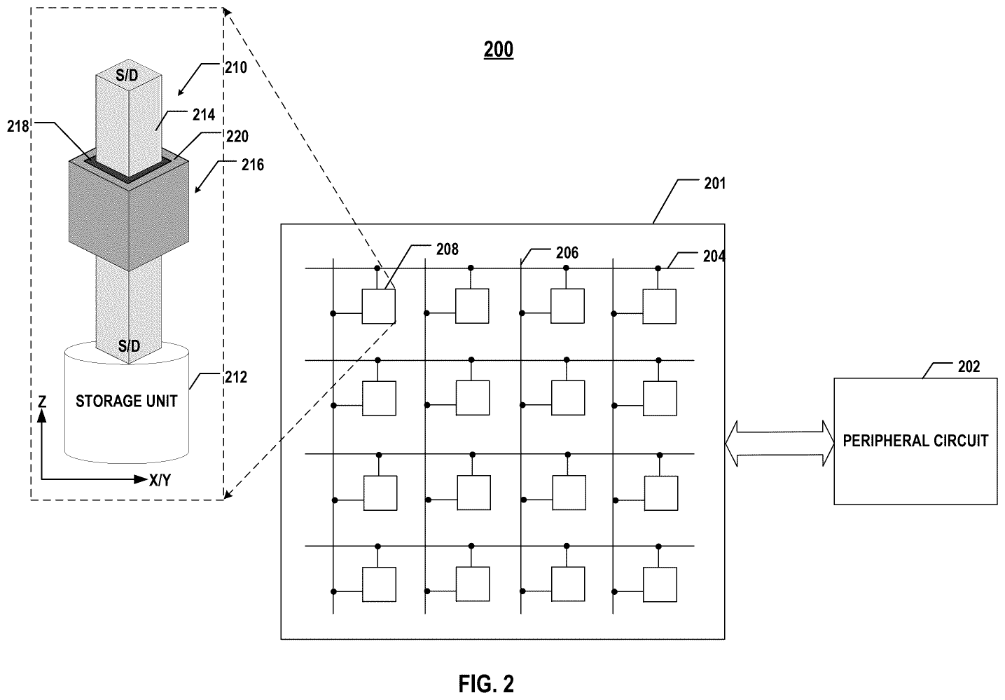

FIG. 2 illustrates a schematic diagram of a memory device 200 including peripheral circuits and an array of memory cells each having a vertical transistor, according to some aspects of the present disclosure. Memory device 200 can include a memory cell array 201 and peripheral circuits 202 coupled to memory cell array 201. 3D memory devices 100 and 101 may be examples of memory device 200 in which memory cell array 201 and peripheral circuits 202 may be included in second and first semiconductor structures 104 and 102, respectively. Memory cell array 201 can be any suitable memory cell array in which each memory cell 208 includes a vertical transistor 210 and a storage unit 212 coupled to vertical transistor 210. In some implementations, memory cell array 201 is a DRAM cell array, and storage unit 212 is a capacitor for storing charge as the binary information stored by the respective DRAM cell. In some implementations, memory cell array 201 is a PCM cell array, and storage unit 212 is a PCM element (e.g., including chalcogenide alloys) for storing binary information of the respective PCM cell based on the different resistivities of the PCM element in the amorphous phase and the crystalline phase. In some implementations, memory cell array 201 is a FRAM cell array, and storage unit 212 is a ferroelectric capacitor for storing binary information of the respective FRAM cell based on the switch between two polarization states of ferroelectric materials under an external electric field.

As shown in FIG. 2, memory cells 208 can be arranged in a two-dimensional (2D) array having rows and columns. Memory device 200 can include word lines 204 coupling peripheral circuits 202 and memory cell array 201 for controlling the switch of vertical transistors 210 in memory cells 208 located in a row, as well as bit lines 206 coupling peripheral circuits 202 and memory cell array 201 for sending data to and/or receiving data from memory cells 208 located in a column. That is, each word line 204 is coupled to a respective row of memory cells 208, and each bit line is coupled to a respective column of memory cells 208.

As shown in FIG. 2, in some implementations, vertical transistor 210 includes a semiconductor body 214 extending vertically (in the z-direction) above the substrate (not shown). That is, semiconductor body 214 can extend above the top surface of the substrate to expose not only the top surface of semiconductor body 214, but also one or more side surfaces thereof. As shown in FIG. 2, for example, semiconductor body 214 can have a cuboid shape to expose four sides thereof. It is understood that semiconductor body 214 may have any suitable 3D shape, such as a polyhedron shape or a cylinder shape. That is, the cross-section of semiconductor body 214 in the plan view (e.g., in the x-y plane) can have a square shape, a rectangular shape (or a trapezoidal shape), a circular (or an oval shape), or any other suitable shapes. Semiconductor body 214 can be formed from the substrate (e.g., by etching or epitaxy) and thus, has the same semiconductor material (e.g., silicon crystalline silicon) as the substrate (e.g., a silicon substrate).

As shown in FIG. 2, vertical transistor 210 can also include a gate structure 216 in contact with one or more sides of semiconductor body 214, i.e., in one or more planes of the side surface(s) of the active region. In other words, the active region of vertical transistor 210, i.e., semiconductor body 214, can be at least partially surrounded by gate structure 216. Gate structure 216 can include a gate dielectric 218 over one or more sides of semiconductor body 214, e.g., in contact with four side surfaces of semiconductor body 214 as shown in FIG. 2. Gate structure 216 can also include a gate electrode 220 over and in contact with gate dielectric 218. Gate dielectric 218 can include any suitable dielectric materials, such as silicon oxide, silicon nitride, silicon oxynitride, or high-k dielectrics. For example, gate dielectric 218 may include silicon oxide, i.e., gate oxide. Gate electrode 220 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 220 may include doped polysilicon, i.e., a gate poly. In some implementations, gate electrode 220 includes multiple conductive layers, such as a W layer over a TiN layer. It is understood that gate electrode 220 and word line 204 may be a continuous conductive structure in some examples. In other words, gate electrode 220 may be viewed as part of word line 204 that forms gate structure 216, or word line 204 may be viewed as the extension of gate electrode 220 to be coupled to peripheral circuits 202.

As shown in FIG. 2, vertical transistor 210 can further include a pair of a source and a drain (S/D, dope regions, a.k.a., source electrode and drain electrode) formed at the two ends of semiconductor body 214 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 216 in the vertical direction (the z-direction). In other words, gate structure 216 is formed vertically between the source and drain. As a result, one or more channels (not shown) of vertical transistor 210 can be formed in semiconductor body 214 vertically between the source and drain when a gate voltage applied to gate electrode 220 of gate structure 216 is above the threshold voltage of vertical transistor 210. That is, each channel of vertical transistors 210 is also formed in the vertical direction along which semiconductor body 214 extends, according to some implementations.

In some implementations, as shown in FIG. 2, vertical transistor 210 is a multi-gate transistor. That is, gate structure 216 can be in contact with more than one side of semiconductor body 214 (e.g., four sides in FIG. 2) to form more than one gate, such that more than one channel can be formed between the source and drain in operation. The multi-gate vertical transistors can include double-gate vertical transistors (e.g., dual-side gate vertical transistors), tri-gate vertical transistors (e.g., tri-side gate vertical transistors), and gate-all-around (GAA) vertical transistors.

It is understood that although vertical transistor 210 is shown as a multi-gate transistor in FIG. 2, the vertical transistors disclosed herein may also include single-gate transistors. That is, gate structure 216 may be in contact with a single side of semiconductor body 214, for example, for the purpose of increasing the transistor and memory cell density. It is also understood that although gate dielectric 218 is shown as being separate (i.e., a separate structure) from other gate dielectrics of adjacent vertical transistors (not shown), gate dielectric 218 may be part of a continuous dielectric layer having multiple gate dielectrics of vertical transistors. It is further understood that in some examples, memory device 200 may include planar transistors, such as lateral multiple-gate transistors (e.g., FinFET), instead of vertical transistors 210.

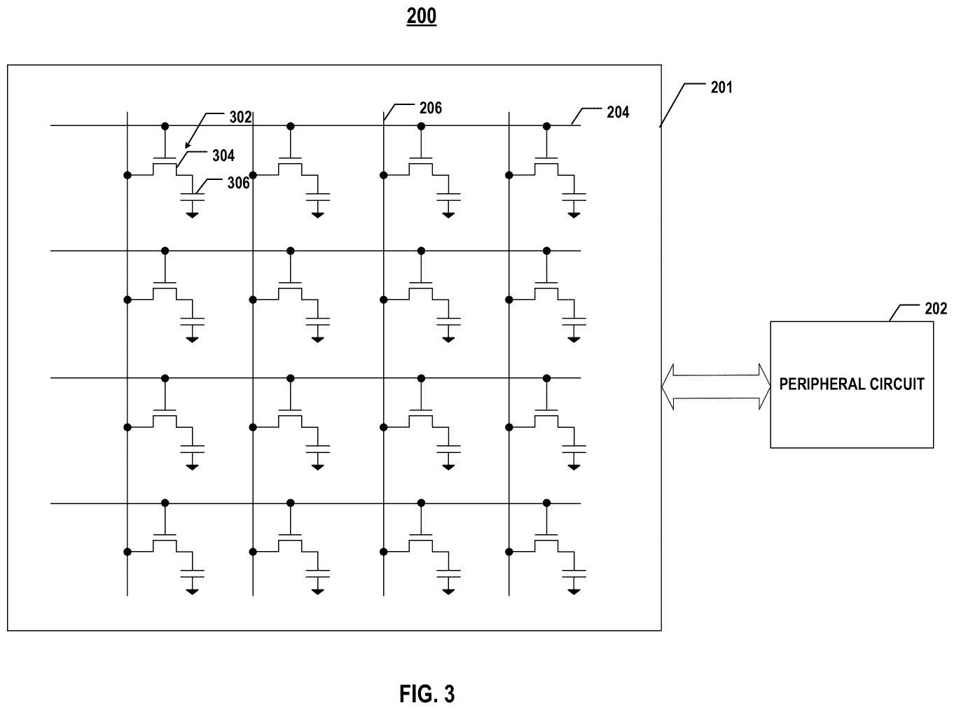

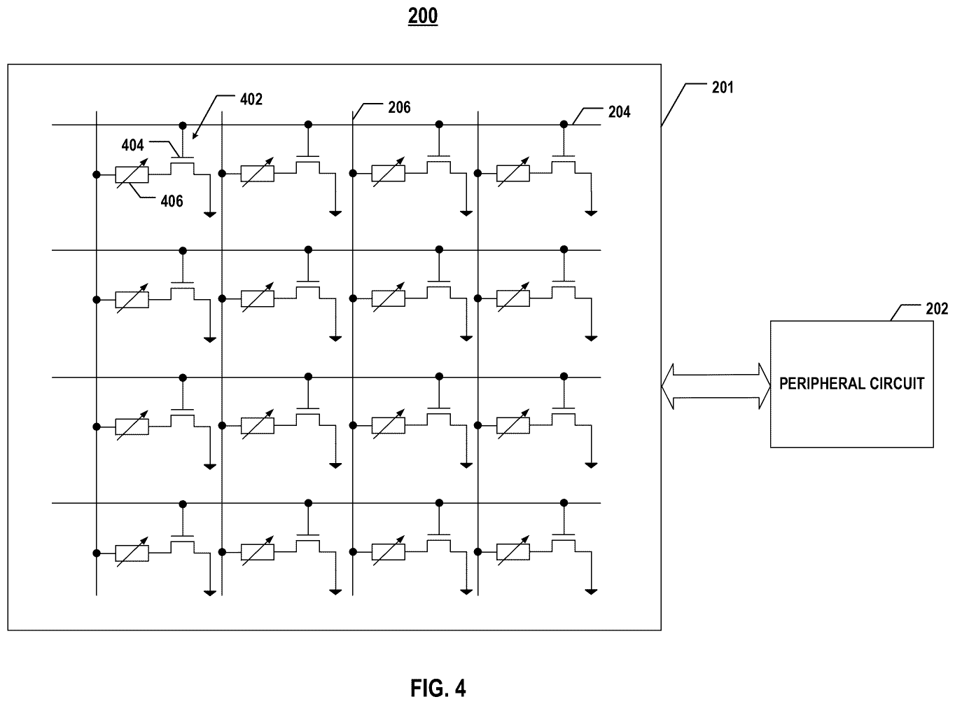

As shown in FIG. 2, storage unit 212 can be coupled to the source or the drain of vertical transistor 210. Storage unit 212 can include any devices that are capable of storing binary data (e.g., 0 and 1), including but not limited to, capacitors for DRAM cells and FRAM cells, and PCM elements for PCM cells. In some implementations, vertical transistor 210 controls the selection and/or the state switch of the respective storage unit 212 coupled to vertical transistor 210. In some implementations as shown in FIG. 3, each memory cell 208 is a DRAM cell 302 including a transistor 304 (e.g., vertical transistors 210 in FIG. 2 or planar transistors, such as FinFETs) and a capacitor 306 (e.g., an example of storage unit 212 in FIG. 2). The gate of transistor 304 (e.g., corresponding to gate electrode 220) may be coupled to word line 204, one of the source and the drain of transistor 304 may be coupled to bit line 206, the other one of the source and the drain of transistor 304 may be coupled to one electrode of capacitor 306, and the other electrode of capacitor 306 may be coupled to the ground. In some implementations as shown in FIG. 4, each memory cell 208 is a PCM cell 402 including a transistor 404 (e.g., vertical transistors 210 in FIG. 2 or planar transistors, such as FinFETs) and a PCM element 406 (e.g., an example of storage unit 212 in FIG. 2). The gate of transistor 404 (e.g., corresponding to gate electrode 220) may be coupled to word line 204, one of the source and the drain of transistor 404 may be coupled to the ground, the other one of the source and the drain of transistor 404 may be coupled to one electrode of PCM element 406, and the other electrode of PCM element 406 may be coupled to bit line 206.

Peripheral circuits 202 can be coupled to memory cell array 201 through bit lines 206, word lines 204, and any other suitable metal wirings. As described above, peripheral circuits 202 can include any suitable circuits for facilitating the operations of memory cell array 201 by applying and sensing voltage signals and/or current signals through word lines 204 and bit lines 206 to and from each memory cell 208. Peripheral circuits 202 can include various types of peripheral circuits formed using CMOS technologies.

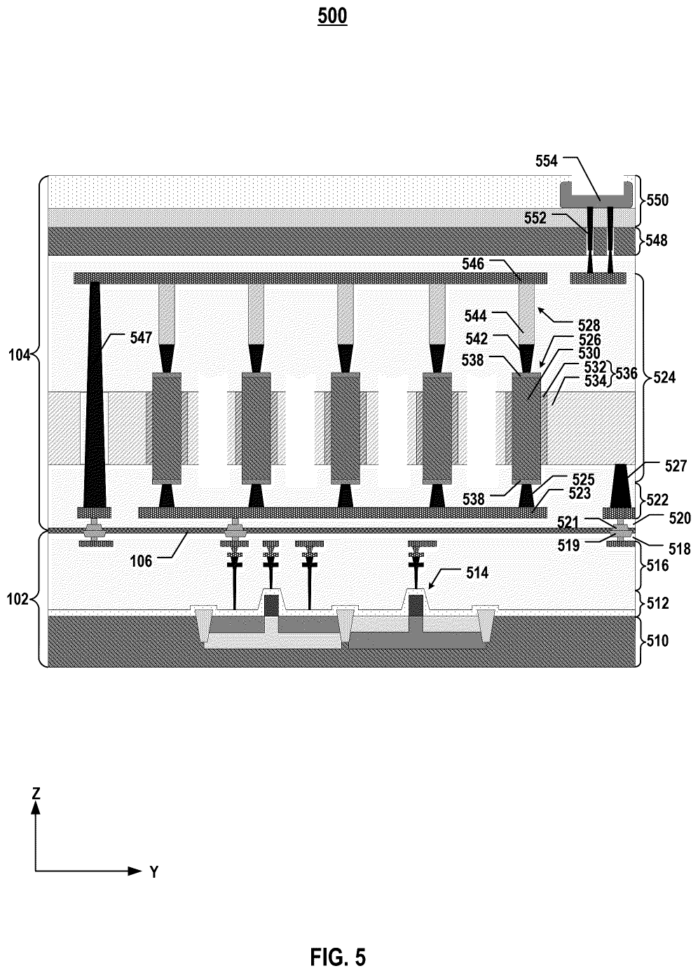

FIG. 5 illustrates a side view of a cross-section of a 3D memory device 500 including vertical transistors, according to some aspects of the present disclosure. 3D memory device 500 may be one example of memory device 200 including multi-gate vertical transistors in which gate structures fully circumscribe semiconductor bodies in the plan view, e.g., GAA vertical transistors. It is understood that FIG. 5 is for illustrative purposes only and may not necessarily reflect the actual device structure (e.g., interconnections) in practice. As one example of 3D memory device 100 described above with respect to FIG. 1A, 3D memory device 500 is a bonded chip including first semiconductor structure 102 and second semiconductor structure 104 stacked over first semiconductor structure 102. First and second semiconductor structures 102 and 104 are jointed at bonding interface 106 therebetween, according to some implementations. As shown in FIG. 5, first semiconductor structure 102 can include a substrate 510, which can include silicon (e.g., single crystalline silicon, c-Si), silicon germanium (SiGe), gallium arsenide (GaAs), germanium (Ge), silicon-on-insulator (SOI), or any other suitable materials.

First semiconductor structure 102 can include peripheral circuits 512 on substrate 510. In some implementations, peripheral circuits 512 includes a plurality of transistors 514 (e.g., planar transistors and/or vertical transistors). Trench isolations (e.g., shallow trench isolations (STIs)) and doped regions (e.g., wells, sources, and drains of transistors 514) can be formed on or in substrate 510 as well.

In some implementations, first semiconductor structure 102 further includes an interconnect layer 516 above peripheral circuits 512 to transfer electrical signals to and from peripheral circuits 512. Interconnect layer 516 can include a plurality of interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. Interconnect layer 516 can further include one or more interlayer dielectric (ILD) layers (also known as “intermetal dielectric (IMD) layers”) in which the interconnect lines and via contacts can form. That is, interconnect layer 516 can include interconnect lines and via contacts in multiple ILD layers. In some implementations, peripheral circuits 512 are coupled to one another through the interconnects in interconnect layer 516. The interconnects in interconnect layer 516 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 5, first semiconductor structure 102 can further include a bonding layer 518 at bonding interface 106 and above interconnect layer 516 and peripheral circuits 512. Bonding layer 518 can include a plurality of bonding contacts 519 and dielectrics electrically isolating bonding contacts 519. Bonding contacts 519 can include conductive materials, such as Cu. The remaining area of bonding layer 518 can be formed with dielectric materials, such as silicon oxide. Bonding contacts 519 and surrounding dielectrics in bonding layer 518 can be used for hybrid bonding. Similarly, as shown in FIG. 5, second semiconductor structure 104 can also include a bonding layer 520 at bonding interface 106 and above bonding layer 518 of first semiconductor structure 102. Bonding layer 520 can include a plurality of bonding contacts 521 and dielectrics electrically isolating bonding contacts 521. Bonding contacts 521 can include conductive materials, such as Cu. The remaining area of bonding layer 520 can be formed with dielectric materials, such as silicon oxide. Bonding contacts 521 and surrounding dielectrics in bonding layer 520 can be used for hybrid bonding. Bonding contacts 521 are in contact with bonding contacts 519 at bonding interface 106, according to some implementations.

Second semiconductor structure 104 can be bonded on top of first semiconductor structure 102 in a face-to-face manner at bonding interface 106. In some implementations, bonding interface 106 is disposed between bonding layers 520 and 518 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, bonding interface 106 is the place at which bonding layers 520 and 518 are met and bonded. In practice, bonding interface 106 can be a layer with a certain thickness that includes the top surface of bonding layer 518 of first semiconductor structure 102 and the bottom surface of bonding layer 520 of second semiconductor structure 104.

In some implementations, second semiconductor structure 104 further includes an interconnect layer 522 including bit lines 523 above bonding layer 520 to transfer electrical signals. Interconnect layer 522 can include a plurality of interconnects, such as MEOL interconnects and BEOL interconnects. In some implementations, the interconnects in interconnect layer 522 also include local interconnects, such as bit lines 523, bit line contacts 525 (which may be omitted in some examples), and word line contacts 527. Interconnect layer 522 can further include one or more ILD layers in which the interconnect lines and via contacts can form. The interconnects in interconnect layer 522 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof. In some implementations, peripheral circuits 512 include word line drivers and row decoders (a.k.a., X-decoders) coupled to word line contacts 527 in interconnect layer 522 through bonding contacts 521 and 519 in bonding layers 520 and 518 and interconnect layer 516. In some implementations, peripheral circuits 512 include bit line drivers and column decoders (a.k.a., Y-decoders) coupled to bit lines 523 and bit line contacts 525 in interconnect layer 522 through bonding contacts 521 and 519 in bonding layers 520 and 518 and interconnect layer 516.

In some implementations, second semiconductor structure 104 includes a DRAM device in which memory cells are provided in the form of an array of DRAM cells 524 above interconnect layer 522 and bonding layer 520. That is, interconnect layer 522 including bit lines 523 can be disposed between bonding layer 520 and array of DRAM cells 524. It is understood that the cross-section of 3D memory device 500 in FIG. 5 may be made along the bit line direction (the y-direction), and one bit line 523 in interconnect layer 522 extending laterally in the y-direction may be coupled to a column of DRAM cells 524.

Each DRAM cell 524 can include a vertical transistor 526 (e.g., an example of vertical transistors 210 in FIG. 2) and capacitor 528 (e.g., an example of storage unit 212 in FIG. 2) coupled to the vertical transistor 526. DRAM cell 524 can be a 1T1C cell consisting of one transistor and one capacitor. It is understood that DRAM cell 524 may be of any suitable configurations, such as 2T1C cell, 3T1C cell, etc.

Vertical transistor 526 can be a MOSFET used to switch a respective DRAM cell 524. In some implementations, vertical transistor 526 includes a semiconductor body 530 (i.e., the active region in which multiple channels can form) extending vertically (in the z-direction), and a gate structure 536 in contact with a plurality of sides of semiconductor body 530. As described above, as in a GAA vertical transistor, semiconductor body 530 can have a cuboid shape or a cylinder shape, and gate structure 536 can fully circumscribe semiconductor body 530 in the plan view. Gate structure 536 includes a gate electrode 534 and a gate dielectric 532 laterally between gate electrode 534 and semiconductor body 530, according to some implementations. For example, for semiconductor body 530 having a cylinder shape, semiconductor body 530, gate dielectric 532, and gate electrode 534 may be disposed radially from the center of vertical transistor 526 in this order. In some implementations, gate dielectric 532 surrounds and contacts semiconductor body 530, and gate electrode 534 surrounds and contacts gate dielectric 532.

As shown in FIG. 5, vertical transistor 526 can further include a source and a drain (both referred to as 538 as their locations may be interchangeable) disposed at the two ends (the upper end and lower end) of semiconductor body 530, respectively, in the vertical direction (the z-direction). In some implementations, one of source and drain 538 (e.g., at the upper end in FIG. 5) is coupled to capacitor 528, and the other one of source and drain 538 (e.g., at the lower end in FIG. 5) is coupled to bit line 523 (e.g., through bit line contact 525 or directly).

In some implementations, semiconductor body 530 includes semiconductor materials, such as single crystalline silicon, polysilicon, amorphous silicon, Ge, any other semiconductor materials, or any combinations thereof. In one example, semiconductor body 530 may include single crystalline silicon. Source and drain 538 can be doped with N-type dopants (e.g., P or As) or P-type dopants (e.g., B or Ga) at a desired doping level. In some implementations, a silicide layer, such as a metal silicide layer, is formed between source and drain 538 and bit line contacts 525 or first electrode 542 to reduce the contact resistance. In some implementations, gate dielectric 532 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. In some implementations, gate electrode 534 includes conductive materials including, but not limited to W, Co, Cu, Al, TiN, TaN, polysilicon, silicides, or any combination thereof. In some implementations, gate electrode 534 includes multiple conductive layers, such as a W layer over a TiN layer. In one example, gate structure 536 may be a “gate oxide/gate poly” gate in which gate dielectric 532 includes silicon oxide and gate electrode 534 includes doped polysilicon. In another example, gate structure 536 may be a high-k metal gate (HKMG) in which gate dielectric 532 includes a high-k dielectric and gate electrode 534 includes a metal.

Since gate electrode 534 may be part of a word line or extend in the word line direction as a word line, although not directly shown in FIG. 5, second semiconductor structure 104 of 3D memory device 500 can also include a plurality of word lines (referred to as 534 as well) each extending in the word line direction (the x-direction). Each word line 534 can be coupled to a row of DRAM cells 524. That is, bit line 523 and word line 534 can extend in two perpendicular lateral directions, and semiconductor body 530 of vertical transistor 526 can extend in the vertical direction perpendicular to the two lateral directions in which bit line 523 and word line 534 extend. Word lines 534 are in contact with word line contacts 527, according to some implementations. In some implementations, word lines 534 include conductive materials including, but not limited to W, Co, Cu, Al, TiN, TaN, polysilicon, silicides, or any combination thereof. In some implementations, word line 534 includes multiple conductive layers, such as a W layer over a TiN layer.

As shown in FIG. 5, word lines 534 can be coupled to peripheral circuits 512 in first semiconductor structure 102 through word line contacts 527 in interconnect layer 522, bonding contacts 521 and 519 in bonding layers 520 and 518, and the interconnects in interconnect layer 516. Similarly, bit lines 523 in interconnect layer 522 can be coupled to peripheral circuits 512 in first semiconductor structure 102 through bonding contacts 521 and 519 in bonding layers 520 and 518 and the interconnects in interconnect layer 516.

As shown in FIG. 5, in some implementations, capacitor 528 includes a first electrode 542 above and in contact with source or drain 538 of vertical transistor 526, e.g., the upper end of semiconductor body 530. Capacitor 528 can also include a capacitor dielectric 544 above and in contact with first electrode 542, and a second electrode 546 above and in contact with capacitor dielectric 544. That is, capacitor 528 can be a vertical capacitor in which electrodes 542 and 546 and capacitor dielectric 544 are stacked vertically (in the z-direction), and capacitor dielectric 544 can be sandwiched between electrodes 542 and 546. In some implementations, each first electrode 542 is coupled to source or drain 538 of a respective vertical transistor 526 in the same DRAM cell, while all second electrodes 546 are parts of a common plate coupled to the ground, e.g., a common ground. As shown in FIG. 5, second semiconductor structure 104 can further include a capacitor contact 547 in contact with the common plate of second electrodes 546 for coupling second electrodes 546 of capacitor 528 to peripheral circuits 512 or to the ground directly.

It is understood that the structure and configuration of capacitor 528 are not limited to the example in FIG. 5 and may include any suitable structure and configuration, such as a planar capacitor, a stack capacitor, a multi-fins capacitor, a cylinder capacitor, a trench capacitor, or a substrate-plate capacitor. In some implementations, capacitor dielectric 544 includes dielectric materials, such as silicon oxide, silicon nitride, or high-k dielectrics including, but not limited to, Al₂O₃, HfO₂, Ta₂O₅, ZrO₂, TiO₂, or any combination thereof. It is understood that in some examples, capacitor 528 may be a ferroelectric capacitor used in a FRAM cell, and capacitor dielectric 544 may be replaced by a ferroelectric layer having ferroelectric materials, such as lead zirconate titanate (PZT) or strontium bismuth tantalate (SBT). In some implementations, electrodes 542 and 546 include conductive materials including, but not limited to W, Co, Cu, Al, TiN, TaN, polysilicon, silicides, or any combination thereof.

In some implementations, second semiconductor structure 104 further includes a substrate 548 disposed above DRAM cells 524. It is understood that in some examples, substrate 548 may not be included in second semiconductor structure 104. As shown in FIG. 5, second semiconductor structure 104 can further include a pad-out interconnect layer 550 above substrate 548 and DRAM cells 524. Pad-out interconnect layer 550 can include interconnects, e.g., contact pads 554, in one or more ILD layers. Pad-out interconnect layer 550 and interconnect layer 522 can be formed on opposite sides of DRAM cells 524. In some implementations, the interconnects in pad-out interconnect layer 550 can transfer electrical signals between 3D memory device 500 and outside circuits, e.g., for pad-out purposes. In some implementations, second semiconductor structure 104 further includes one or more contacts 552 extending through substrate 548 and part of pad-out interconnect layer 550 to couple pad-out interconnect layer 550 to DRAM cells 524 and interconnect layer 522. As a result, peripheral circuits 512 can be coupled to DRAM cells 524 through interconnect layers 516 and 522 as well as bonding layers 520 and 518, and peripheral circuits 512 and DRAM cells 524 can be coupled to outside circuits through contacts 552 and pad-out interconnect layer 550. Contact pads 554 and contacts 552 can include conductive materials including, but not limited to, W, Co, Cu, Al, silicides, or any combination thereof.

It is understood that the pad-out of 3D memory devices is not limited to from second semiconductor structure 104 having DRAM cells 524 as shown in FIG. 5 and may be from first semiconductor structure 102 having peripheral circuit 512 (not shown). It is also understood that the relative vertical positions between the semiconductor body and the respective gate structure and word line are not limited to the example shown in FIG. 5 in which both the upper and lower ends of semiconductor body 530 extend beyond gate structure 536 (and word line 534), respectively, depending on the various fabrication processes. It is further understood that the dielectric materials of the ILD layers into which the semiconductor bodies extend are not limited to the example shown in FIG. 5 in which the ILD layers include silicon oxide, e.g., the same material as the ILD layer in which capacitors 528 are formed, depending on the various fabrication processes. It is still further understood that the air gaps between word lines may be partially or fully filled with dielectrics. It is still further understood that more than one DRAM cell array may be stacked over one another to vertically scale up the number of DRAM cells.

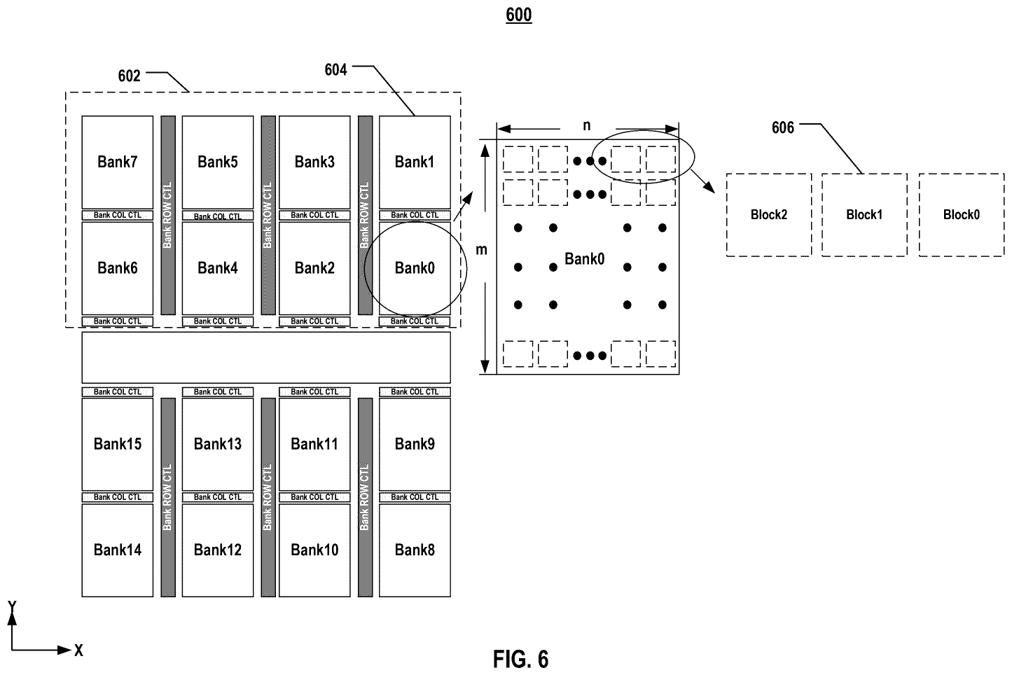

FIG. 6 illustrates a schematic plan view of a memory device 600, according to some aspects of the present disclosure. Memory device 600 may be an example of memory device 200. As shown in FIG. 6, memory device 600 can include one or more memory array structure 602 (e.g., memory dies). Memory array structures 602 can be mutually independent in performing a read operation, a program operation, or an erase operation. Each memory array structure 602 can include a plurality of memory banks 604. For example, as shown in FIG. 6, memory array structure 602 may include eight memory banks 604. Each memory bank 604 may include a plurality of memory blocks 606. For example, as shown in FIG. 6, memory bank 604 may include m (in the word line/x direction)×n (in the bit line/y direction) memory blocks 606. In other words, memory array structure 602 can include a plurality of memory blocks 606, such as 8×m×n memory blocks 606 in the example of FIG. 6.

Memory array structures 602 can be mutually independent in performing a read operation, a program operation, or an erase operation in parallel, thereby increasing the operation speed. To enable its independent operation, memory device 600 can include a peripheral circuit structure (not shown in FIG. 6) including a set of peripheral circuits (e.g., 202 in FIG. 2) for each memory array structure 602, such as word line drivers, X-decoders, bit line sense amplifiers, precharge voltage drivers, discharge voltage drivers, etc. For example, memory device 600 may be an example of 3D memory devices 100 and 101 of FIGS. 1A and 1B, where each memory array structure 602 may be an example of second semiconductor structure 104, and the corresponding peripheral circuit structure may be an example of first semiconductor structure 102 stacked above or below memory array structure 602. Memory array structure 602 (and memory blocks 606 therein) and the corresponding peripheral circuit structure (and the peripheral circuits therein) can partially or fully overlap with each other.

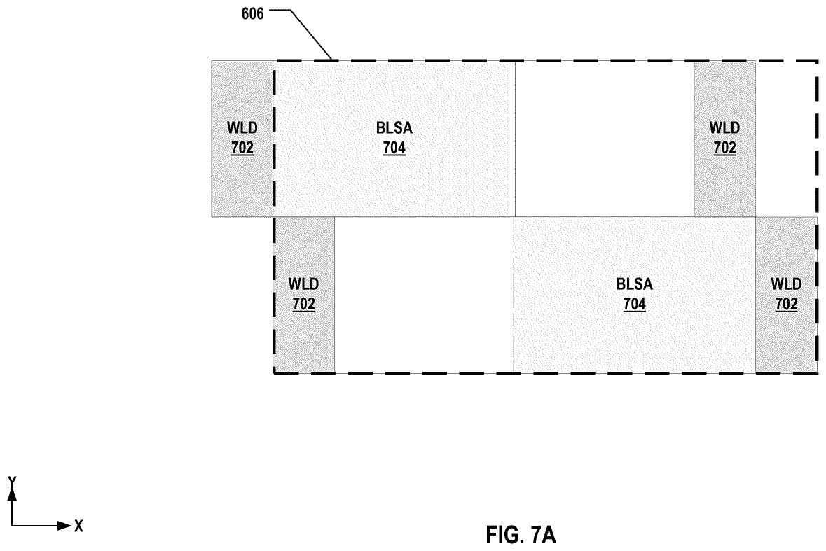

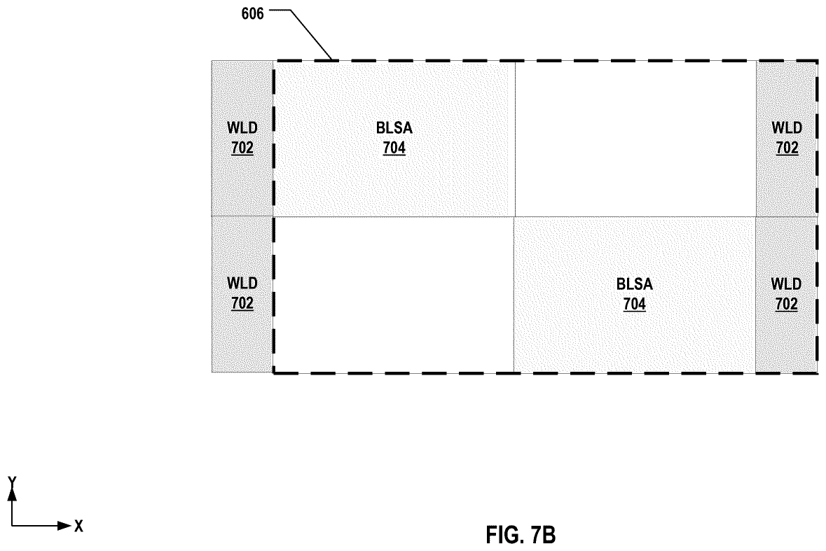

For example, FIGS. 7A and 7B illustrate schematic plan views of memory block 606 and peripheral circuits overlapping with memory block 606 in memory device 600, according to various aspects of the present disclosure. As shown in FIGS. 7A and 7B, the peripheral circuits corresponding to and facilitating the operations of memory block 606 can include word line drivers (WLDs) 702 coupled to the word lines of memory block 606 and bit line sense amplifier (BLSAs) 704 coupled to the bit lines of memory block 606. Word line driver 702 can be configured to drive the word lines by applying word line voltages at various desired levels. Word line driver 702 can include one or more string drivers, each of which can include one or more transistors. Bit line sense amplifier 704 can be configured to amplify and detect current signals in the bit lines. By stacking memory array structure 602 (and memory blocks 606 therein) and the corresponding peripheral circuit structure (and word line drivers 702 and bit line sense amplifiers 704 therein) vertically, word line drivers 702 and bit line sense amplifiers 704 overlap (partially or fully) with memory block 606 vertically, according to some implementations.

It is understood that FIGS. 7A and 7B each shows one of memory blocks 606 shown in FIG. 6, and memory block 606 and corresponding word line drivers 702 and bit line sense amplifiers 704 may be repeated in both the bit line direction (the y-direction) and the word line direction (the x-direction), as shown in FIG. 6, to form an m×n array in each memory bank 604. As a result, in memory device 600, word line drivers 702 can be arranged in the bit line direction (the y-direction). In some implementations, as shown in FIG. 7A, word line drivers 702 are arranged in a zig-zag manner along the edges of memory blocks 606. In other words, word line drivers 702 can be staggered in the word line direction (the x-direction), as shown in FIG. 7A. In some implementations, as shown in FIG. 7B, word line drivers 702 are arranged in a straight-line along the edges of memory blocks 606. In other words, word line drivers 702 can be aligned in the word line direction (the x-direction), as shown in FIG. 7B.

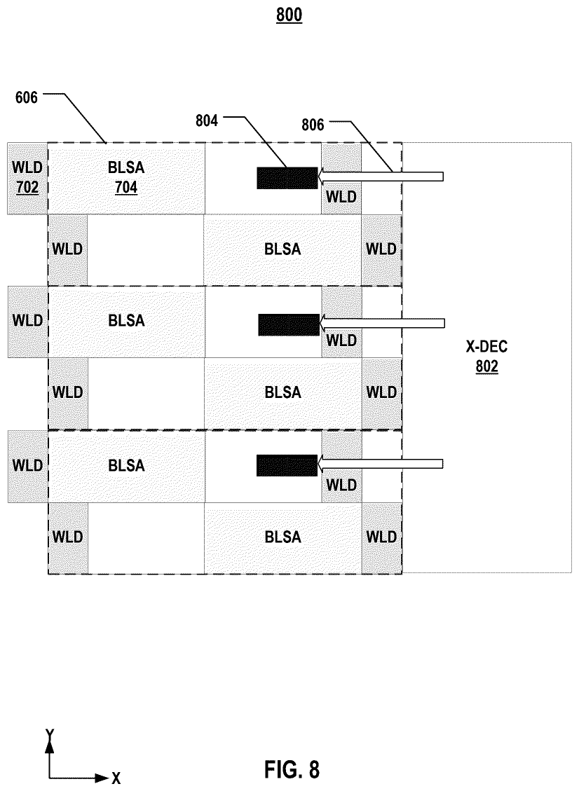

FIG. 8 illustrates a schematic plan view of a memory device 800 including memory blocks 606 and precharge/discharge voltage drivers 804. X-decoders 802, another type of peripheral circuits, may be offset from memory blocks 606 in the word line direction (the x-direction). That is, X-decoders 802 may be arranged in a region not overlapped with memory blocks 606 in the vertical direction. For example, as shown in FIG. 6, X-decoders 802 may be arranged between memory banks 604 in the word line direction (the x-direction) as parts of bank row control peripheral circuits (Bank ROW CTL). As shown in FIG. 8, in this example, precharge voltage drivers and/or discharge voltage drivers 804 (also referred to herein as “precharge/discharge voltage drivers”), still another type of peripheral circuits, may also overlap with memory blocks 606 in the vertical direction. In order to make electrical connections between X-decoders 802 and precharge/discharge voltage drivers 804, metal routings may have to cross word line drivers 702, which are arranged along the edges of memory blocks 606. For example, each precharge/discharge voltage driver 804 may be coupled to X-decoders 802 by a larger number of control signal routings 806 (e.g., 18 control signal routings) across a respective word line driver 702, which may be difficult for layout design and consume large areas for routing. Moreover, as word line drivers 702 include high voltage devices (e.g., high voltage transistors), which have a significant coupling effect, large noises may be introduced from the larger number of control signal routings 806 across word line drivers 702 as well.

The layout design of the precharge voltage drivers and/or discharge voltage drivers and their interconnect routings are optimized in the present disclosure to reduce the routing area and coupling effect. Consistent with the scope of the present disclosure, different portions of a precharge voltage driver and/or a discharge voltage driver (e.g., the precharge/discharge circuit and the evaluating circuit) are detached and physically separated into different regions, such that the number of control signal routing across the respective word line driver is reduced (e.g., to only one).

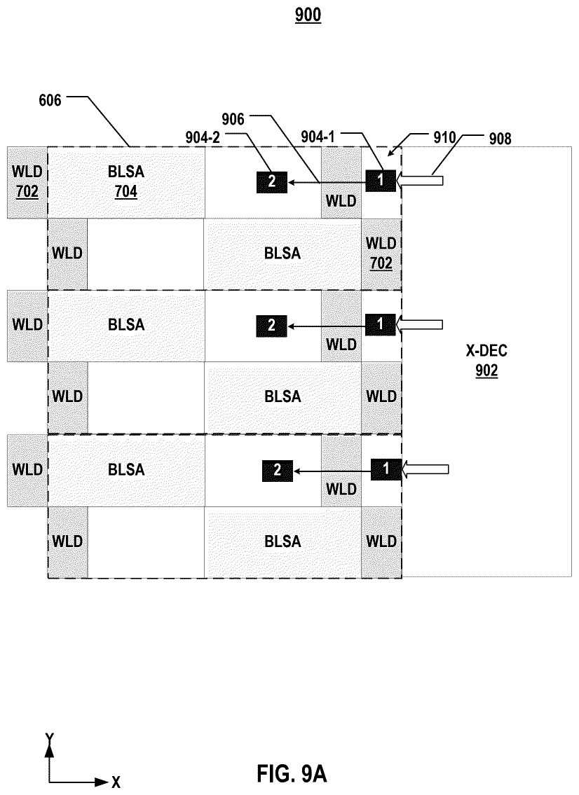

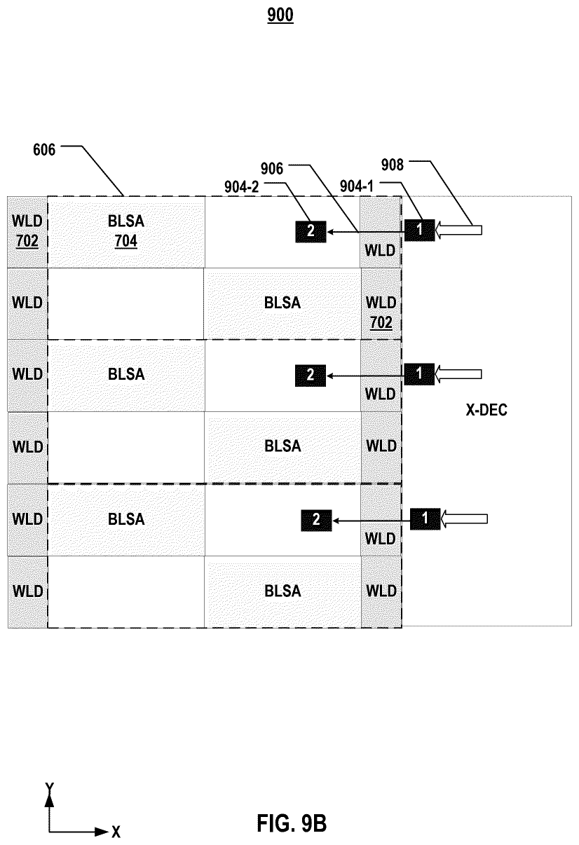

FIGS. 9A and 9B illustrate schematic plan views of a memory device 900 including memory blocks 606 and precharge/discharge voltage drivers 904, according to various aspects of the present disclosure. Memory device 900 may be an example of memory device 600 in FIG. 6. As shown in FIGS. 9A, and 9B, one or more X-decoders 902 are offset from memory blocks 606 (dashed line boxes) in the word line direction (the x-direction) and are arranged in a region not overlapped with memory blocks 606 in the vertical direction, according to some implementations. In some implementations, as shown in FIG. 6, X-decoders 902 are arranged between memory banks 604 in the word line direction (the x-direction) as parts of bank row control peripheral circuits (Bank ROW CTL). X-decoders 902 can be configured to determine the select word line based on the received address and enable word line driver 702 and precharge/discharge voltage driver 904 corresponding to the select word line.

As shown in FIGS. 9A and 9B, memory device 900 also includes word line drivers 702 and bit line sense amplifiers 704 overlapping with memory block 606 in the vertical direction, according to some implementations. It is understood that word line drivers 702 and/or bit lit sense amplifiers 704 may at least partially (i.e., partially or fully) overlap with memory block 606 in the vertical direction. In memory device 900, word line drivers 702 can be arranged in the bit line direction (the y-direction). In some implementations, as shown in FIG. 9A, word line drivers 702 are arranged in a zig-zag manner along the edges of memory blocks 606. In other words, word line drivers 702 can be staggered in the word line direction (the x-direction), as shown in FIG. 9A. As shown in FIG. 9A, the edges of memory blocks 606 and word line drivers 702 define regions 910, according to some implementations. In other words, X-decoders 902 and word line drivers 702 can enclose regions 910 since word line drivers 702 are arranged in a zig-zag manner. In some implementations, as shown in FIG. 9B, word line drivers 702 are arranged in a straight-line along the edges of memory blocks 606. In other words, word line drivers 702 can be aligned in the word line direction (the x-direction), as shown in FIG. 9B. Different from the example in FIG. 9B, regions 910 are not defined by the edges of memory blocks 606 and word line drivers 702 in FIG. 9B since word line drivers 702 are arranged in a straight-line.

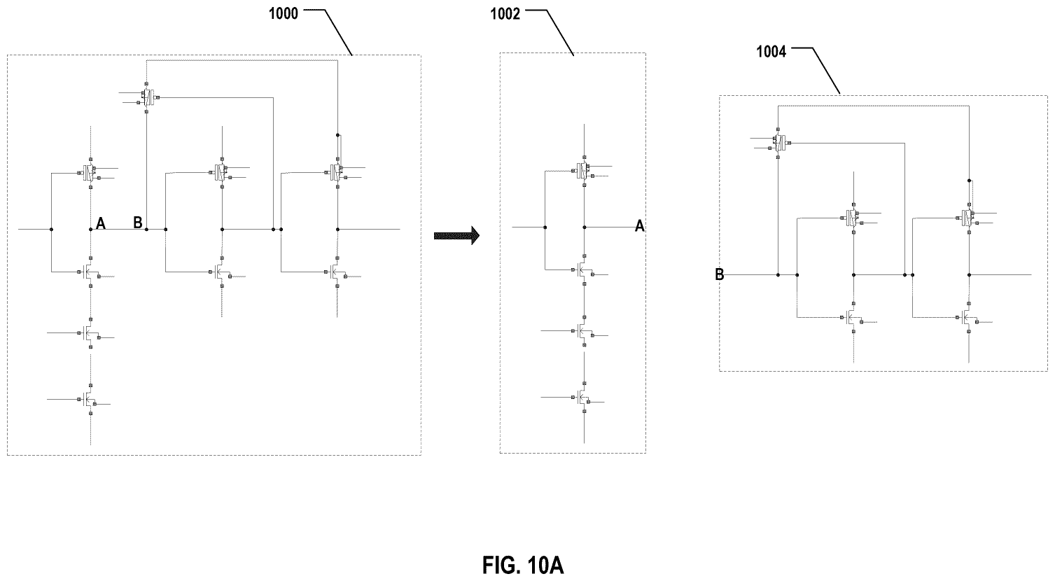

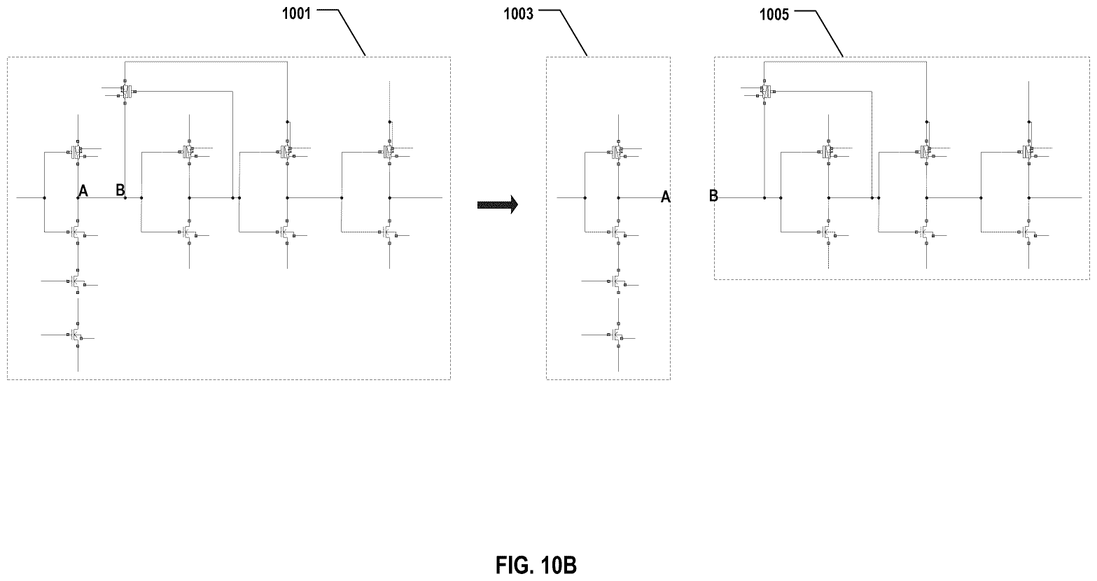

In some implementations, precharge/discharge voltage driver 904 includes a precharge voltage driver 1000, as shown in FIG. 10A, configured to precharge the word lines of respective memory block 606. For example, in a precharge phase of an operation (e.g., a program or read operation), precharge voltage driver 1000 may set the corresponding word line to a predetermined voltage level before the operation, preparing the word line for the operation. As shown in FIG. 10A, precharge voltage driver 1000 can include a precharge circuit 1002 and an evaluating circuit 1004, and an output node A of precharge circuit 1002 is coupled to an input node B of evaluating circuit 1004. Evaluating circuit 1004 can be configured to monitor the voltage level and provide feedback to precharge circuit 1002 to achieve the desired precharge voltage level on the corresponding word line. A number of input nodes of precharge circuit 1002 are configured to receive control signals from X-decoder 902, and an output node of evaluating circuit 1004 is configured to output a precharge signal to the select word line of respective memory block 606. In some implementations, precharge/discharge voltage drivers 904 includes a discharge voltage driver 1001, as shown in FIG. 10B, configured to discharge the word lines of respective memory block 606. For example, in a discharge phase of an operation (e.g., a program or read operation), discharge voltage driver 1001 may discharge the corresponding word line after the operation, preparing the word line for the next operation. As shown in FIG. 10B, discharge voltage driver 1001 can include a discharge circuit 1003 and an evaluating circuit 1005, and an output node A of discharge circuit 1003 is coupled to an input node B of evaluating circuit 1005. Evaluating circuit 1005 can be configured to monitor the voltage level and provide feedback to discharge circuit 1003 to fully discharge the corresponding word line. A number of input nodes of discharge circuit 1003 are configured to receive control signals from X-decoder 902, and an output node of evaluating circuit 1005 is configured to output a discharge signal to signal to the select word line of respective memory block 606.

Referring back to FIGS. 9A and 9B, each precharge/discharge voltage driver 904 (e.g., precharge voltage driver 1000 or discharge voltage driver 1001) can include a precharge/discharge circuit 904-1 “1” (e.g., precharge circuit 1002 or discharge circuit 1003) and an evaluating circuit 904-2 “2” (e.g., evaluating circuit 1004 or 1005) physically separated by respective word line driver 702 in the word line direction (the x-direction). That is, precharge/discharge circuit 904-1 and evaluating circuit 904-2 of each precharge/discharge voltage driver 904 are disposed on opposite sides of respective word line driver 702 in the word line direction (the x-direction) in memory device 900, instead of on the same side in memory device 800 (as shown in FIG. 8), according to some implementations. It is understood that in some examples, each precharge/discharge voltage driver 904 may include repeated, multiple precharge voltage drivers 1000 shown in FIG. 10A or repeated, multiple discharge voltage drivers 1001 shown in FIG. 10B. Similarly, each precharge/discharge circuit 904-1 may include repeated, multiple precharge circuits 1002 shown in FIG. 10A or repeated, multiple discharge circuits 1003 shown in FIG. 10B, and each evaluating circuit 904-2 may include repeated, multiple evaluating circuits 1004 shown in FIG. 10A or repeated, multiple evaluating circuits 1005 shown in FIG. 10B.

In some implementations, although physically separated, precharge/discharge circuit 904-1 and evaluating circuit 904-2 of each precharge/discharge voltage driver 904 are not electrically separated, and are coupled to each other by one control signal routing 906 across respective word line driver 702. For example, control signal routing 906 may be formed between an output node (e.g., node A in FIGS. 10A and 10B) of precharge/discharge circuit 904-1 and an input node (e.g., node B in FIGS. 10A and 10B) of evaluating circuit 904-2, such that the control signal may still be sent from precharge/discharge circuit 904-1 to evaluating circuit 904-2. Since there is only one connection between precharge/discharge circuit 904-1 and evaluating circuit 904-2 of each precharge/discharge voltage driver 904, there is only one control signal routing 906 that needs to cross respective word line 702, as opposed to a number (e.g., 18) of control signal routings 806. Thus, the interconnect routing under or above memory blocks 606 can be simplified, and the area needed for the control signal routing and noises coupled from word line drivers 702 can be reduced.

On the other hand, as shown in FIGS. 9A and 9B, since precharge/discharge circuits 904-1 of precharge/discharge voltage drivers 904 are no longer physically separated from X-decoders 902 by word line drivers 702 (as shown in FIG. 8), X-decoders 902 can be coupled to precharge/discharge circuit 904-1 of each precharge/discharge voltage driver 904 by additional control signal routings 908 without crossing respective word line driver 702. For example, control signals may be sent from X-decoders 902 to the input nodes of precharge/discharge circuits 904-1 that are on the same side of word line drivers 702.

Precharge/discharge voltage drivers 904 can fully or partially overlap with memory blocks 606 in the vertical direction. As shown in FIGS. 9A and 9B, evaluating circuits 904-2 of precharge/discharge voltage drivers 904 can be disposed on one side of word line drivers 702 that is away from X-decoders 902 and closer to memory blocks 606. In some implementations, evaluating circuits 904-2 overlap with memory blocks 606 in the vertical direction, like word line drivers 702.

On the other hand, precharge/discharge circuits 904-1 of precharge/discharge voltage drivers 904 can be disposed on the other side of word line drivers 702 that is closer to X-decoders 902 and away from memory blocks 606 and thus, may or may not overlap with memory blocks 606 depending on the arrangements of word line drivers 702. In some implementations in which word line drivers 702 are arranged in a zig-zag manner as shown in FIG. 9A, precharge/discharge circuits 904-1 of each precharge/discharge voltage driver 904 is arranged in respective region 910 between the edges of respective memory block 606 and respective word line driver 702. Since each region 910 overlaps with respective memory block 606, each precharge/discharge circuit 904-1 overlaps with respective memory block 606 as well, according to some implementations as shown in FIG. 9A. Thus, precharge/discharge voltage drivers 904 can fully overlap with memory blocks 606 in the vertical direction in FIG. 9A. In contrast, in some implementations in which word line drivers 702 are arranged in a straight-line as shown in FIG. 9B, precharge/discharge circuits 904-1 of each precharge/discharge circuit 904-1 is offset from respective memory block 606, according to some implementations as shown in FIG. 9B. That is, in FIG. 9B, precharge/discharge circuits 904-1 may not overlap with memory blocks 606 in the vertical direction. Thus, precharge/discharge voltage drivers 904 can partially overlap with memory blocks 606 in the vertical direction in FIG. 9B.

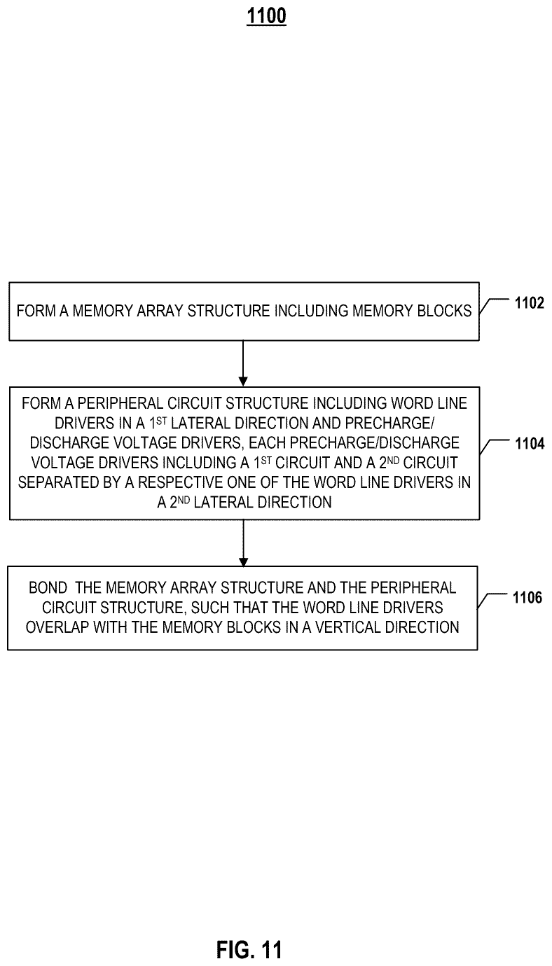

FIG. 11 illustrates a flowchart of a method 1100 for forming a 3D memory device, according to some aspects of the present disclosure. Examples of the 3D memory devices depicted in FIG. 11 include any 3D memory devices disclosed herein, such as 3D memory devices 500 and 900 depicted in FIGS. 5 and 9. FIGS. 5, 9A, 9B, and 11 will be described together. It is understood that the operations shown in method 1100 are not exhaustive and that other operations can be performed as well before, after, or between any of the illustrated operations. Further, some of the operations may be performed simultaneously, or in a different order than shown in FIG. 11.

Referring to FIG. 11, method 1100 starts at operation 1102, in which a memory array structure including memory blocks is formed. In some implementations, each of the memory blocks includes DRAM cells. In some implementations, the memory array structure includes first bonding contacts. As illustrated in FIG. 5, memory array structure 104 including DRAM cells 524 and bonding contacts 521 is formed on substrate 548.

Method 1100 proceeds to operation 1104, as illustrated in FIG. 11, in which a peripheral circuit structure including word line drivers and precharge/discharge voltage drivers is formed. In some implementations, the word line drivers are formed in a first lateral direction. In some implementations, each of the precharge/discharge voltage drivers includes a first circuit and a second circuit physically separated by a respective one of the word line drivers in a second lateral direction perpendicular to the first lateral direction. In some implementations, the first circuit of the precharge/discharge voltage driver includes a precharge/discharge circuit, and the second circuit of the precharge/discharge voltage driver includes an evaluating circuit. In some implementations, the first circuit is coupled to the second circuit by one control signal routing across the respective word line driver. In some implementations, the first lateral direction is a bit line direction, and the second lateral direction is a word line direction. In some implementations, the peripheral circuit structure includes second bonding contacts.

As illustrated in FIG. 5, peripheral circuit structure 102 including peripheral circuits 512 and bonding contacts 519 is formed on substrate 510. As illustrated in FIGS. 9A and 9B, word line drivers 702 are formed in the bit line direction. Each precharge/discharge voltage driver 904 includes precharge/discharge circuit 904-1 and evaluating circuit 904-2 physically separated by respective word line driver 702 in the word line direction. Precharge/discharge circuit 904-1 is coupled to evaluating circuit 904-2 by one control signal routing 906 across respective word line driver 702.

Method 1100 proceeds to operation 1106, as illustrated in FIG. 11, in which the memory array structure and the peripheral circuit structure are bonded, such that the word line drivers in the peripheral circuit structure at least partially overlap with the memory blocks in the memory array structure in a vertical direction. In some implementations, the second bonding contacts are in contact with the first bonding contacts in the vertical direction after the bonding. In some implementations, the bonding includes hybrid bonding in a face-to-face manner. In some implementations, after the bonding, each of the precharge/discharge voltage drivers is coupled to a respective one of the memory blocks and configured to precharge or discharge word lines of the respective memory blocks. In some implementations, the second circuits of the precharge/discharge voltage drivers in the peripheral circuit structure overlap with the memory blocks in the memory array structure in the vertical direction after the bonding.

As illustrated in FIG. 5, peripheral circuit structure 102 and memory array structure 104 are bonded using hybrid bonding in a face-to-face manner such that bonding contacts 519 are in contact with bonding contacts 521 after the bonding. As illustrated in FIGS. 9A and 9B, word line drivers 702 at least partially (partially or fully) overlap with memory blocks 606 in the vertical direction after the bonding. Each precharge/discharge voltage driver 904 is coupled to respective memory block 606 and configured to precharge or discharge the word lines of respective memory block 606. Evaluating circuits 904-2 of precharge/discharge voltage drivers 904 overlap with memory blocks 606 in the vertical direction as well.

In some implementations, the word line drivers are formed in a zig-zag manner along edges of the memory blocks, and the first circuits of the precharge/discharge voltage drivers in the peripheral circuit structure overlap with the memory blocks in the memory array structure in the vertical direction and are formed in regions between the edges of the memory blocks and the word line drivers. As illustrated in FIG. 9A, word line drivers 702 are formed in a zig-zag manner along the edges of memory blocks 606, and precharge/discharge circuits 904-1 overlap with memory blocks 606 in the vertical direction and are formed in regions 910 between the edges of memory blocks 606 and word line drivers 702.

In some implementations, the word line drivers are formed in a straight-line along edges of the memory blocks, and the first circuits of the precharge/discharge voltage drivers in the peripheral circuit structure are offset from the memory blocks in the memory array structure. As illustrated in FIG. 9B, word line drivers 702 are formed in a straight-line along the edges of memory blocks 606, and precharge/discharge circuits 904-1 are offset from memory blocks 606.

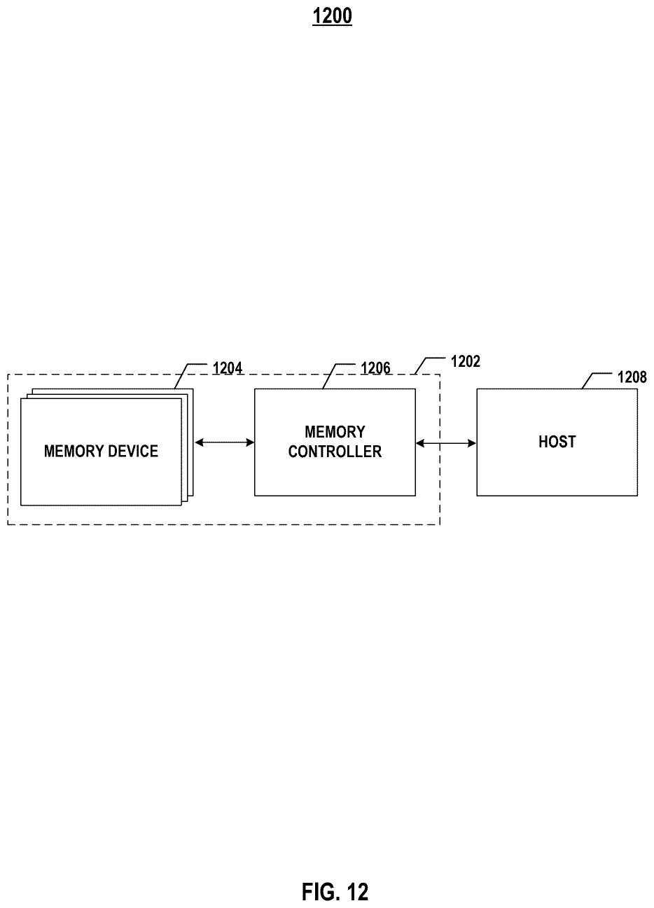

FIG. 12 illustrates a block diagram of an exemplary system 1200 having a memory device 1204, according to some aspects of the present disclosure. System 1200 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 12, system 1200 can include a host 1208 and a memory system 1202 having one or more memory devices 1204 and a memory controller 1206. Host 1208 can be a processor of an electronic device, such as a central processing unit (CPU), or a system-on-chip (SoC), such as an application processor (AP). Host 1208 can be configured to send or receive the data to or from memory devices 1204.

Memory device 1204 can be any memory devices disclosed herein. Memory controller 1206 is coupled to memory device 1204 and host 1208 and is configured to control memory device 1204, according to some implementations. Memory controller 1206 can manage the data stored in memory device 1204 and communicate with host 1208. Memory controller 1206 can be configured to control operations of memory device 1204, such as read, write, and refresh operations. Memory controller 1206 can also be configured to manage various functions with respect to the data stored or to be stored in memory device 1208 including, but not limited to refresh and timing control, command/request translation, buffer and schedule, and power management. In some implementations, memory controller 1206 is further configured to determine the maximum memory capacity that the computer system can use, the number of memory banks, memory type and speed, memory particle data depth and data width, and other important parameters. Any other suitable functions may be performed by memory controller 1206 as well. Memory controller 1206 can communicate with an external device (e.g., host 1208) according to a particular communication protocol. For example, memory controller 1206 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a memory array structure comprising memory blocks; and
a peripheral circuit structure stacked with the memory array structure in a vertical direction and comprising word line drivers and precharge/discharge voltage drivers,
wherein the word line drivers are arranged in a first lateral direction and at least partially overlap with the memory blocks in the memory array structure in the vertical direction; and
each of the precharge/discharge voltage drivers comprises a first circuit and a second circuit physically separated by a respective one of the word line drivers in a second lateral direction perpendicular to the first lateral direction.

2. The memory device of claim 1, wherein the second circuits of the precharge/discharge voltage drivers in the peripheral circuit structure overlap with the memory blocks in the memory array structure in the vertical direction.

3. The memory device of claim 1, wherein the first circuit of the precharge/discharge voltage driver comprises a precharge/discharge circuit, and the second circuit of the precharge/discharge voltage driver comprises an evaluating circuit.

4. The memory device of claim 1, wherein the first circuit is coupled to the second circuit by one control signal routing across the respective word line driver.

5. The memory device of claim 1, wherein
the word line drivers are arranged in a straight-line along edges of the memory blocks; and
the first circuits of the precharge/discharge voltage drivers in the peripheral circuit structure are offset from the memory blocks in the memory array structure.

6. The memory device of claim 1, wherein
the word line drivers are arranged in a zig-zag manner along edges of the memory blocks; and
the first circuits of the precharge/discharge voltage drivers in the peripheral circuit structure overlap with the memory blocks in the memory array structure in the vertical direction and are arranged in regions between the edges of the memory blocks and the word line drivers.

7. The memory device of claim 1, wherein each of the precharge/discharge voltage drivers is coupled to a respective one of the memory blocks and configured to precharge or discharge word lines of the respective memory blocks.

8. The memory device of claim 1, wherein the first lateral direction is a bit line direction, and the second lateral direction is a word line direction.

9. The memory device of claim 1, wherein the memory array structure comprises first bonding contacts, and the peripheral circuit structure comprises second bonding contacts in contact with the first bonding contacts in the vertical direction.

10. The memory device of claim 1, wherein each of the memory blocks comprises dynamic random-access memory (DRAM) cells.

11. A method for forming a memory device, comprising:
forming a memory array structure comprising memory blocks; and
forming a peripheral circuit structure comprising word line drivers and precharge/discharge voltage drivers,
wherein the word line drivers are formed in a first lateral direction;
each of the precharge/discharge voltage drivers comprises a first circuit and a second circuit physically separated by a respective one of the word line drivers in a second lateral direction perpendicular to the first lateral direction; and
the word line drivers in the peripheral circuit structure at least partially overlap with the memory blocks in the memory array structure in a vertical direction.

12. The method of claim 11, further comprising bonding the memory array structure and the peripheral circuit structure.

13. The method of claim 11, wherein the second circuits of the precharge/discharge voltage drivers in the peripheral circuit structure overlap with the memory blocks in the memory array structure in the vertical direction.

14. The method of claim 11, wherein the first circuit of the precharge/discharge voltage driver comprises a precharge/discharge circuit, and the second circuit of the precharge/discharge voltage driver comprises an evaluating circuit.

15. The method of claim 11, wherein the first circuit is coupled to the second circuit by one control signal routing across the respective word line driver.

16. The method of claim 11, wherein
the word line drivers are formed in a straight-line along edges of the memory blocks; and
the first circuits of the precharge/discharge voltage drivers in the peripheral circuit structure are offset from the memory blocks in the memory array structure.

17. The method of claim 11, wherein
the word line drivers are formed in a zig-zag manner along edges of the memory blocks; and
the first circuits of the precharge/discharge voltage drivers in the peripheral circuit structure overlap with the memory blocks in the memory array structure in the vertical direction and are formed in regions between the edges of the memory blocks and the word line drivers.

18. The method of claim 11, wherein each of the precharge/discharge voltage drivers is coupled to a respective one of the memory blocks and configured to precharge or discharge word lines of the respective memory blocks.

19. The method of claim 11, wherein the memory array structure comprises first bonding contacts, and the peripheral circuit structure comprises second bonding contacts in contact with the first bonding contacts in the vertical direction after the bonding.

20. A system, comprising:
a memory device, comprising:
a memory array structure comprising memory blocks; and
a peripheral circuit structure stacked with the memory array structure in a vertical direction and comprising word line drivers and precharge/discharge voltage drivers, wherein the word line drivers are arranged in a first lateral direction and at least partially overlap with the memory blocks in the memory array structure in the vertical direction; and
each of the precharge/discharge voltage drivers comprises a first circuit and a second circuit physically separated by a respective one of the word line drivers in a second lateral direction perpendicular to the first lateral direction; and
a memory controller coupled to the memory device and configured to control the memory device.
